(19) United States
(12) Patent Application Publication
(10) Pub. No.: US 2018/0076367 A1
(43) Pub. Date: Mar. 15, 2018

(54) OPTOELECTRONIC COMPONENT AND METHOD FOR THE PRODUCTION THEREOF

(71) Applicant: OSRAM Opto Semiconductors GmbH, Regensburg (DE)

(72) Inventor: Matthias Knoerr, Tanjung Tokong (MY)

(21) Appl. No.: 15/564,499

(22) PCT Filed: Apr. 6, 2016
(86) PCT No.: PCT/EP2016/057509

§ 371 Date: Oct. 5, 2017

(30) Foreign Application Priority Data
Apr. 10, 2015 (DE) 10 2015 105 486.8

(51) Int. Cl. H01L 33/60; H01L 33/54; H01L 33/62; H01L 33/00; H01L 33/50

(52) U.S. Cl. CPC H01L 33/60; H01L 33/54; H01L 33/62; H01L 33/0079; H01L 25/167; H01L 2933/0058; H01L 2933/005; H01L 2933/0041; H01L 2933/0066; H01L 33/505

(57) ABSTRACT

An optoelectronic component includes an optoelectronic semiconductor chip at least partly enclosed by a molded body, wherein a front side of the molded body is covered by a reflecting film, at least in some sections, and a section of the reflecting film is enclosed between the optoelectronic semiconductor chip and the molded body.

### TECHNICAL FIELD

This disclosure relates to an optoelectronic component and a method of producing an optoelectronic component.

### BACKGROUND

DE 10 2009 036 621 A1 discloses a method of producing optoelectronic components in which optoelectronic semiconductor chips are embedded in a molded body covering all the side surfaces of the optoelectronic semiconductor chips. Upper and lower sides of the optoelectronic semiconductor chips remain exposed. Electric through contacts can be embedded in the molded body together with the optoelectronic semiconductor chips.

### SUMMARY

I provide an optoelectronic component including an optoelectronic semiconductor chip at least partly enclosed by a molded body, wherein a front side of the molded body is covered by a reflecting film, at least in some sections, and a section of the reflecting film is enclosed between the optoelectronic semiconductor chip and the molded body.

I also provide a method of producing an optoelectronic component including providing a carrier having an upper side which has an elevated and a recessed region; arranging an optoelectronic semiconductor chip between the elevated region of the upper side of the carrier and a reflecting film, wherein a front side of the optoelectronic semiconductor chip faces the carrier, and a rear side of the optoelectronic semiconductor chip faces the reflecting film; forming a molded body on a rear side of the reflecting film, facing away from the optoelectronic semiconductor chip, wherein the optoelectronic semiconductor chip is at least partly enclosed by the molded body, wherein a section of the reflecting film is enclosed between the optoelectronic semiconductor chip and the molded body; and detaching the molded body, the reflecting film and the optoelectronic semiconductor chip from the upper side of the carrier, wherein at least part of the reflecting film remains on a front side of the molded body.

### BRIEF DESCRIPTION OF THE DRAWINGS

FIG. 1 schematically shows a sectioned side view of a carrier with optoelectronic semiconductor chips arranged thereon.

FIG. 2 schematically shows the carrier with a reflecting film arranged over the optoelectronic semiconductor chips.

FIG. 3 schematically shows a sectioned side view of a molded body formed over the optoelectronic semiconductor chips, the carrier and the reflecting film.

FIG. 4 schematically shows the molded body following the detachment from the carrier.

FIG. 5 schematically shows the carrier following exposure of the rear sides of the optoelectronic semiconductor chips.

FIG. 6 schematically shows the carrier with metallizations arranged on the rear sides of the optoelectronic semiconductor chips.

FIG. 7 schematically shows the carrier with wavelength-converting material arranged over the front side of the optoelectronic semiconductor chips.

FIG. 8 schematically shows optoelectronic components formed by dividing up the molded body.

FIG. 9 schematically shows a plan view of the upper side of the carrier with optoelectronic semiconductor chips, protective chips and via chips arranged thereon.

FIG. 10 schematically shows a plan view of the carrier following the arrangement of the reflecting film over the optoelectronic semiconductor chips, protective chips and via chips.

FIG. 11 schematically shows a plan view of the reflecting film arranged on the front side of the molded body after the forming of the molded body.

FIG. 12 schematically shows a sectioned side view of the molded body.

FIG. 13 schematically shows a further plan view of the upper side of the carrier with optoelectronic semiconductor chips and protective chips arranged thereon.

FIG. 14 schematically shows a plan view of the reflecting film arranged over the optoelectronic semiconductor chips and the protective chips.

FIG. 15 schematically shows a plan view of the reflecting film arranged on the front side of the molded body after the forming of the molded body.

FIG. 16 schematically shows a first sectioned side view of the molded body.

FIG. 17 schematically shows a second sectioned side view of the molded body.

FIG. 18 schematically shows a sectioned side view of the carrier according to a further example.

FIG. 19 schematically shows the carrier with the reflecting film arranged over the optoelectronic semiconductor chips.

FIG. 20 schematically shows a sectioned side view of the molded body formed over the carrier, the optoelectronic semiconductor chips and the reflecting film.

FIG. 21 schematically shows the molded body following the detachment from the carrier.

FIG. 22 schematically shows the molded body following the arrangement of electrically conductive connections on the front side of the molded body.

FIG. 23 schematically shows the molded body following the arrangement of wavelength-converting material over the front sides of the optoelectronic semiconductor chips.

FIG. 24 schematically shows optoelectronic components formed by dividing up the molded body.

### LIST OF DESIGNATIONS

10 Optoelectronic component
100 Optoelectronic semiconductor chip
101 Front side
102 Rear side
110 Front-side contact pad
120 Rear-side contact pad
200 Protective chip
201 Front side
202 Rear side
300 Via chip
301 Front side
302 Rear side
310 Through contact
320 Via structure
400 Carrier
401 Upper side
410 Elevated region
420 Recessed region
425 Outer region
430 Further elevated region
440 Film
450 Opening
500 Reflecting film
501 Front side
502 Rear side
510 Close-fitting film section
520 Interposed film section
530 Enclosed film section
540 First film section
550 Second film section
560 Opening
600 Molded body
601 Front side
602 Rear side
610 Reflector
620 Anchorage
700 Metallization
710 Wavelength-converting material
720 Dielectric
730 Electrically conductive connection

### DETAILED DESCRIPTION

My optoelectronic component comprises an optoelectronic semiconductor chip, which is at least partly enclosed by a molded body. A front side of the molded body is covered by a reflecting film, at least in some sections. A section of the reflecting film is enclosed between the optoelectronic semiconductor chip and the molded body.

The reflecting film covering the front side of the molded body, at least in some sections, can advantageously increase the reflectance of the front side of the molded body of the optoelectronic component. As a result, light losses effected by absorption on the front side of the molded body are advantageously reduced in the optoelectronic component, which means that the optoelectronic component can have a high efficiency.

As a result of the inclusion of a section of the reflecting film between the optoelectronic semiconductor chip and the molded body, the reflecting film reaches until directly on a radiation emission face of the optoelectronic semiconductor chip but does not cover the latter. In this way, optimal coverage of the front side of the molded body of the optoelectronic component is advantageously achieved. The precise relative alignment between the radiation emission face of the optoelectronic semiconductor chip and the reflecting film can advantageously result in a self-adjusting manner during production of the optoelectronic component.

The molded body may form on its front side a reflector, which is elevated above a front side of the optoelectronic semiconductor chip. The reflector is covered here by the reflecting film, at least in some sections. The reflector formed by the molded body of the optoelectronic component can effect focusing of electromagnetic radiation emitted by the optoelectronic component. As a result of the covering of the reflector, at least in some sections, by the reflecting film, the reflector of the optoelectronic component advantageously has beneficial reflection characteristics.

A front side and a rear side of the optoelectronic semiconductor chip may not be covered by the molded body. As a result, making electric contact with electric contact pads of the optoelectronic semiconductor chip arranged on the front side and/or the rear side of the optoelectronic semiconductor chip is advantageously made easier.

The molded body may have an electrically conductive through contact extending from the front side to a rear side of the molded body. There is here an electrically conductive connection between an electric contact pad of the optoelectronic semiconductor chip, which is arranged on a front side of the optoelectronic semiconductor chip, and the electrically conductive through contact. Advantageously, the electrically conductive through contact of the optoelectronic component permits electric contact to be made with the electric contact pad of the optoelectronic semiconductor chip on the rear side of the molded body, the electric contact pad being arranged on the front side of the optoelectronic semiconductor chip. As a result, the optoelectronic component may, for example, be suitable as an SMD component for surface mounting, for example, for surface mounting by reflow soldering.

A method of producing an optoelectronic component comprises steps of providing a carrier having an upper side having an elevated and a recessed region, arranging an optoelectronic semiconductor chip between the elevated region of the upper side of the carrier and a reflecting film, wherein a front side of the optoelectronic semiconductor chip faces the carrier, and a rear side of the optoelectronic semiconductor chip faces the reflecting film, forming a molded body on a rear side of the reflecting film, facing away from the optoelectronic semiconductor chip, wherein the optoelectronic semiconductor chip is at least partly enclosed by the molded body, wherein a section of the reflecting film is enclosed between the optoelectronic semiconductor chip and the molded body, and detaching the molded body, the reflecting film and the optoelectronic semiconductor chip from the upper side of the carrier, wherein at least part of the reflecting film remains on a front side of the molded body.

Advantageously, the method permits production of an optoelectronic component having a molded body, the front side of which is covered by the reflecting film, at least in some sections. As a result, the front side of the molded body of the optoelectronic component that can be obtained by the method has a high reflectance, which means that light losses caused by absorption on the front side of the molded body are reduced.

The fact that, during the forming of the molded body, a section of the reflecting film is enclosed between the optoelectronic semiconductor chip and the molded body results in precise alignment of the reflecting film and of the optoelectronic semiconductor chip relative to each other, in which the reflecting film reaches until directly on a radiation emission face of the optoelectronic semiconductor chip, without covering the latter. This precise alignment advantageously results automatically and in a self-adjusting manner in the method, which permits simple and economical performance of the method.

The molded body may be formed such that the front side of the molded body at least partly reproduces the upper side of the carrier. The forming of the upper side of the carrier used in this method, having an elevated and a recessed region, advantageously makes it possible as a result to three-dimensionally model the front side of the molded body of the optoelectronic component that can be obtained by the method. Here, the front side of the molded body results as a negative of the shape of the upper side of the carrier, at least in some sections and approximately. As a result, it is made possible, for example, to form the front side of the molded body of the optoelectronic component that can be obtained by the method as a reflector that can effect focusing of electromagnetic radiation emitted by the optoelectronic component.

The molded body may be formed such that the front side of the optoelectronic semiconductor chip is not covered by the material of the molded body. As a result, electromagnetic radiation emitted at the front side of the optoelectronic semiconductor chip can advantageously be emitted by the optoelectronic component that can be obtained by the method. In addition, it is advantageously made possible to make contact with an electric contact pad of the optoelectronic semiconductor chip that is possibly arranged on the front side of the optoelectronic semiconductor chip. As a result of the fact that the front side of the optoelectronic semiconductor chip is already not covered by the material of the molded body during forming of the molded body, it is advantageously not necessary to expose the front side of the optoelectronic semiconductor chip after the forming of the molded body.

The reflecting film may be connected integrally to the rear side of the optoelectronic semiconductor chip before forming the molded body. Advantageously, the reflecting film in the optoelectronic component that can be obtained by the method can then be used as a rear-side metallization of the optoelectronic semiconductor chip. The integral connection of the reflecting film to the rear side of the optoelectronic semiconductor chip can be carried out, for example, by a method similar to wafer bonding, laser welding or friction welding.

The carrier may have at least one opening, through which the reflecting film is sucked onto the upper side of the carrier before forming the molded body. Advantageously, in this way particularly good reproduction of the upper side of the carrier by the front side of the molded body can be achieved. In particular, as a result of sucking the reflecting film onto the upper side of the carrier, a bubble-free arrangement of the reflecting film on the front side of the molded body of the optoelectronic component that can be attained by the method can be ensured.

The reflecting film may have at least one opening. Here, during forming of the molded body, part of the material of the molded body passes through the opening in the reflecting film. In this way, the reflecting film in the area of the opening of the reflecting film is anchored in the molded body, which means that a particularly stable connection between the reflecting film and the front side of the molded body of the optoelectronic component that can be obtained by the method can be achieved.

The method may comprise a further step of arranging a wavelength-converting material over the front side of the optoelectronic semiconductor chip. The wavelength-converting material can, for example, have wavelength-converting particles embedded in a matrix material, for example, a silicone. The wavelength-converting material can be provided to convert the electromagnetic radiation emitted by the optoelectronic semiconductor chip of the optoelectronic component that can be obtained by the method at least partly into electromagnetic radiation of a different, typically higher, wavelength.

The reflecting film may have an electrically conductive first film section and an electrically conductive second film section insulated with respect to the first film section. Advantageously, in the optoelectronic component that can be obtained by the method, the reflecting film can also be used for the electric wiring of the optoelectronic component.

An electrically conductive element may be arranged on the rear side of the second film section of the reflecting film. The molded body is formed here such that, after the forming of the molded body, the electrically conductive element is accessible on a rear side of the molded body. In addition, following the detachment from the carrier, a further step is carried out to create an electrically conductive connection between an electric contact pad of the optoelectronic semiconductor chip, that is arranged on the front side of the optoelectronic semiconductor chip, and the electrically conductive element. Advantageously, in the optoelectronic component that can be obtained by the method, the electrically conductive element then constitutes an electrically conductive connection between the electric contact pad of the optoelectronic semiconductor chip, that is arranged on the front side of the optoelectronic semiconductor chip, and the rear side of the molded body. This makes it possible to make electric contact with the optoelectronic component that can be obtained by the method on the rear side of the molded body. The electrically conductive element can already be directly accessible on the rear side of the molded body after forming the molded body. The electrically conductive element can, however, also be made accessible after forming the molded body by partial removal of the material of the molded body on the rear side of the molded body.

An electrically conductive via chip may be arranged between the upper side of the carrier and the second film section of the reflecting film and is enclosed by the molded body. In addition, following detachment from the carrier, a further step is carried out to create an electrically conductive connection between an electric contact pad of the optoelectronic semiconductor chip, that is arranged on the front side of the optoelectronic semiconductor chip, and the via chip. As a result, the via chip in the optoelectronic component that can be obtained by the method provides an electrically conductive connection between the electric contact pad of the optoelectronic semiconductor chip, that is arranged on the front side of the optoelectronic semiconductor chip, and the rear side of the molded body, which makes it possible to make electric contact with the optoelectronic component that can be obtained by the method on the rear side of the molded body.

A via chip may be arranged between the upper side of the carrier and the second film section of the reflecting film and is enclosed by the molded body. Part of the second film section is enclosed here between the via chip and the molded body. Following the detachment from the carrier, a step is additionally carried out to create an electrically conductive connection between an electric contact pad of the optoelectronic semiconductor chip, that is arranged on the front side of the optoelectronic semiconductor chip, and the second film section. Advantageously, as a result, in the optoelectronic component that can be obtained by this method, the second film section forms an electrically conductive connection between the electric contact pad of the optoelectronic semiconductor chip, that is arranged on the front side of the optoelectronic semiconductor chip, and the rear side of the molded body. This makes it possible to make electric contact with the optoelectronic component that can be obtained by the method on the rear side of the molded body.

The carrier may be provided with a further elevated region. The recessed region is arranged here between the elevated region and the further elevated region. The first film section is arranged in contact with the rear side of the optoelectronic semiconductor chip. The second film section is arranged to rest on the further elevated region. Following the detachment from the carrier, a step is carried out to create an electrically conductive connection between an electric contact pad of the optoelectronic semiconductor chip, that is arranged on the front side of the optoelectronic semiconductor chip, and the second film section. Advantageously, in the optoelectronic component that can be obtained by this method, the second film section provides an electrically conductive connection between the electric contact pad of the optoelectronic semiconductor chip, that is arranged on the front side of the optoelectronic semiconductor chip, and the rear side of the molded body. This makes it possible to make electric contact with the optoelectronic component on the rear side of the molded body.

The method may comprise further steps of exposing the rear side of the optoelectronic semiconductor chip and arranging a metallization on the rear side of the optoelectronic semiconductor chip. The metallization arranged on the rear side of the optoelectronic semiconductor chip can be used to make electric contact with the optoelectronic component in the optoelectronic component that can be obtained by the method.

Exposure of the rear side of the optoelectronic semiconductor chip may comprise removal of part of the molded body on a rear side of the molded body. The removal of part of the molded body can be carried out, for example, by a grinding process.

The above-described characteristics, features and advantages and the manner in which they are achieved become clearer and considerably more understandable in conjunction with the following description of the examples, which are explained in more detail in conjunction with the drawings.

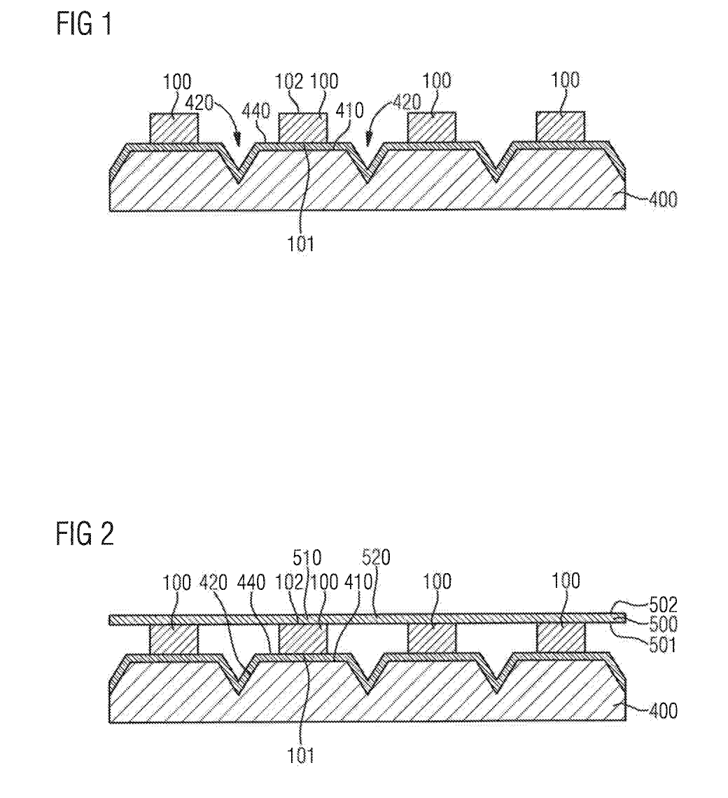

FIG. 1 shows a schematic sectioned side view of part of a carrier 400. The carrier 400 has an upper side 401. The upper side 401 can, for example, have a rectangular shape or the shape of a circular disk.

The upper side 401 of the carrier 400 has elevated regions 410 and regions 420 recessed with respect to the elevated regions 410. The elevated regions 410 form islands delimited by the recessed regions 420. The elevated regions 410 can, for example, be formed rectangularly or in the form of circular disks. The recessed regions 420 form trenches running around the elevated regions 410. The recessed regions 420, for example, have V-enclosed cross sections.

A film 440 is arranged on the upper side 401 of the carrier 400. The film 440 can, for example, be a double-sided adhesive film. The film 440 follows the topography of the upper side 401 of the carrier 400 and covers both the elevated regions 410 and the recessed regions 420. It is expedient that the film 440 has a low thickness as compared with the lateral dimensions of the elevated regions 410 and the recessed regions 420 so that the topography of the upper side 401 of the carrier 400 is changed only a little by the film 440.

Optoelectronic semiconductor chips 100 are arranged on the film 440 over the upper side 401 of the carrier 400. The optoelectronic semiconductor chips 100 can be, for example, light-emitting diode chips (LED chips).

The optoelectronic semiconductor chips 100 are arranged above the elevated regions 410 of the carrier 400. In the example illustrated in FIG. 1, an optoelectronic semiconductor chip 100 is arranged over each elevated region 410 of the upper side 401 of the carrier 400. However, it is also possible to arrange more than one optoelectronic semiconductor chip 100 over each elevated region 410.

Each optoelectronic semiconductor chip 100 has a front side 101 and a rear side 102 opposite the front side 101. The optoelectronic semiconductor chips 100 are arranged over the upper side 401 of the carrier 400 such that the front sides 101 of the optoelectronic semiconductor chips 100 face the upper side 401 of the carrier 400.

FIG. 2 shows a schematic sectioned side view of the carrier 400 in a processing state following the illustration of FIG. 1 chronologically.

A reflecting film 500 has been arranged over the rear sides 102 of the optoelectronic semiconductor chips 100 arranged over the upper side 401 of the carrier 400. The reflecting film 500 can, for example, have been stretched over the optoelectronic semiconductor chips 100. The reflecting film 500 has a front side 501 facing the optoelectronic semiconductor chips 100 and a rear side 502 opposite the front side 501. The front side 501 of the reflecting film 500 is in contact with the rear sides 102 of the optoelectronic semiconductor chips 100. The optoelectronic semiconductor chips 100 are therefore arranged between the upper side 401 of the carrier 400 and the front side 501 of the reflecting film.

The reflecting film 500 has a high optical reflectance, at least on its front side 501. The reflecting film 500 can, for example, be formed as a metal foil and, for example, have aluminum or silver. However, the reflecting film 500 can also be formed as a plastic film, for example, and, for example, have a metallic coating which, for example, has aluminum or silver.

The reflecting film 500 has film sections 510 resting on the rear sides 102 of the optoelectronic semiconductor chips 100 and interposed film sections 520 arranged between the close-fitting film sections 510. The interposed film sections 520 are stretched between the close-fitting film sections 510 of the reflecting film 500.

The close-fitting film sections 510 of the reflecting film 500 can connect integrally to the rear sides 102 of the optoelectronic semiconductor chips 100. The integral connection between the close-fitting film sections 510 of the reflecting film 500 and the rear sides 102 of the optoelectronic semiconductor chips 100 can have been produced, for example, by a method similar to wafer bonding, laser welding or friction welding. It is also possible to arrange the optoelectronic semiconductor chips 100 on the front side 501 of the reflecting film 500 first and only then to connect the rear sides 102 of the optoelectronic semiconductor chips 100 integrally to the close-fitting film sections 510 of the reflecting film 500, and to arrange the reflecting film 500 with the optoelectronic semiconductor chips 100 arranged thereon over the upper side 401 and the carrier 400 in the manner illustrated in FIG. 2.

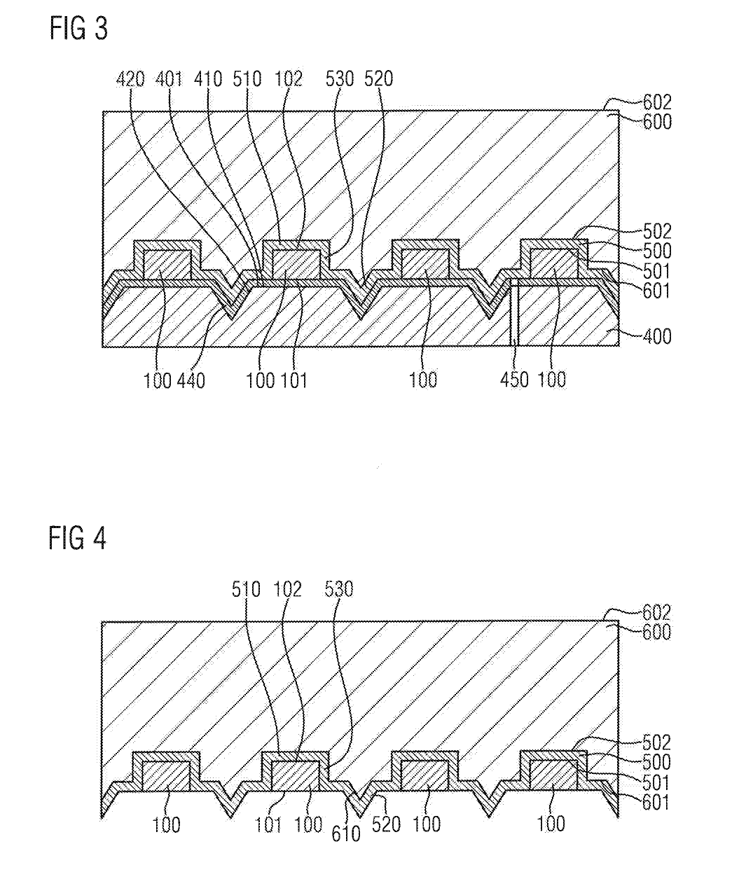

FIG. 3 shows a schematic sectioned side view of the carrier 400 in a processing state following the illustration of FIG. 2 chronologically.

A molded body 600 has been formed on the rear side 502 of the reflecting film 500 facing away from the optoelectronic semiconductor chips 100. The material of the molded body 600 has at least partly enclosed the optoelectronic semiconductor chips 100. The interposed film sections 520 of the reflecting film 500 have been forced by the material of the molded body 600 in the direction toward the upper side 401 of the carrier 400 so that substantially no empty space has remained between the film 440 arranged on the upper side 401 of the carrier 400 and the front side 501 of the reflecting film 500. This can have been assisted during forming of the molded body 600 by the reflecting film 500 having been sucked onto the upper side 401 of the carrier 400 through one or more openings 450 arranged in the carrier. However, the openings 450 do not necessarily have to be present.

A front side 601 of the molded body 600, facing the upper side 401 of the carrier 400, at least partly reproduces the upper side 401 of the carrier 400 having the elevated regions 410 and the recessed regions 420 so that the front side 601 of the molded body 600 forms a negative of the upper side 401 of the carrier 400.

Parts of the interposed film sections 520 of the reflecting film 500 have been enclosed between the front side 601 of the molded body 600 and the film 440 arranged on the upper side 401 of the carrier 400. Further parts of the interposed film sections 520 of the reflecting film 500 have been enclosed between the molded body 600 and the side flanks of the optoelectronic semiconductor chips 100 that extend between the front sides 101 and the rear sides 102 of the optoelectronic semiconductor chips 100, and form enclosed film sections 530. The enclosed film sections 530 are arranged between the film sections 510 resting on the rear sides 102 of the optoelectronic semiconductor chips 100 and the film sections enclosed between the front side 601 of the molded body 600 and the film 440 on the upper side 401 of the carrier 400.

The molded body 600 has an electrically insulating molding material, for example, a plastic material in particular, for example, an epoxy resin. The molded body 600 can have been formed by a shaping method (molding method), in particular, for example, by pressure injection molding (transfer molding) or by compression molding.

In the example shown in FIG. 3, a rear side 602 of the molded body 600, opposite the front side 601, is arranged over the rear sides 102 of the optoelectronic semiconductor chips 100 and the film sections 510 of the reflecting film 500 resting on the rear sides 102 so that the film sections 510 of the reflecting film 500 resting on the rear sides 102 of the optoelectronic semiconductor chips 100 are covered by the material of the molded body 600. However, it is likewise possible to form the molded body 600 such that the film sections 510 of the reflecting film 500 resting on the rear sides 102 of the optoelectronic semiconductor chips 100 are not covered by the material of the molded body 600, and the rear side 602 of the molded body 600 ends substantially flush with the film sections 510 resting on the rear sides 102 of the optoelectronic semiconductor chips 100.

FIG. 4 shows a schematic sectioned side view of the molded body 600 in a processing state following the illustration of FIG. 3 chronologically.

The molded body 600, the reflecting film 500 and the optoelectronic semiconductor chips 100 embedded in the molded body 600 have been detached jointly from the film 440 arranged on the upper side 401 of the carrier 400. The reflecting film 500 has remained on the molded body 600. In this way, the front side 601 of the molded body 600 is at least partly covered by the reflecting film 500.

Since the front sides 101 of the optoelectronic semiconductor chips 100 were protected by the film 440 arranged on the upper side 401 of the carrier 400 during the forming of the molded body 600, the front sides 101 of the optoelectronic semiconductor chips 100 have not been covered by the material of the molded body 600 and are exposed following the detachment of the molded body 600 from the upper side 401 of the carrier 400.

Since the front side 601 of the molded body 600 has reproduced the upper side 401 of the carrier 400, the molded body 600 forms on its front side 601 reflectors 610 elevated above the front sides 101 of the optoelectronic semiconductor chips. The reflectors 610 on the front side 601 of the molded body 600 are covered by the reflecting film 500, which means that the reflectors 610 have a high optical reflectance. Each optoelectronic semiconductor chip 100 is assigned a reflector 610. The respective reflector 610 is provided to focus electromagnetic radiation emitted from the optoelectronic semiconductor chip 100 at the front side 101 thereof.

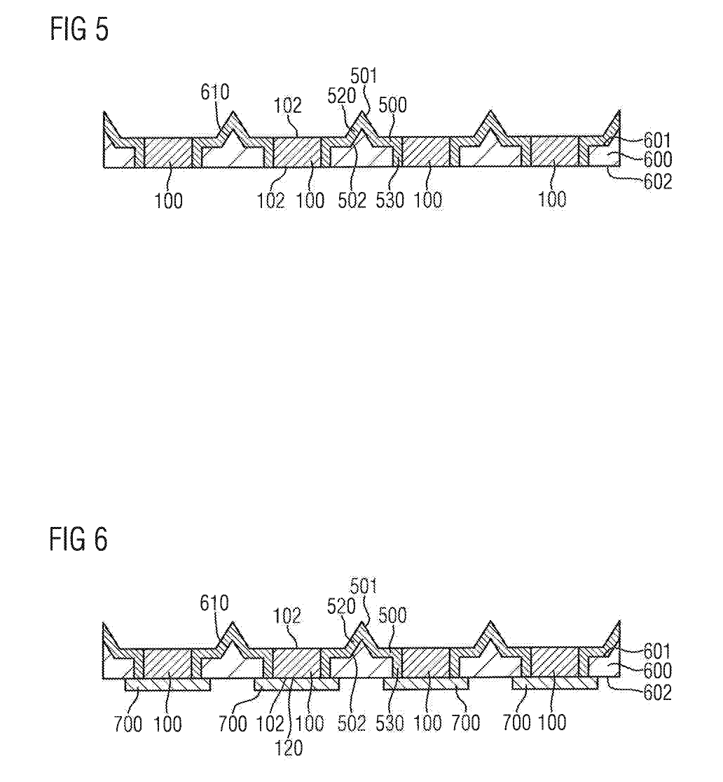

FIG. 5 shows a schematic sectioned side view of the molded body 600 in a processing state following the illustration of FIG. 4 chronologically.

Part of the material of the molded body 600 on the rear side 602 of the molded body 600, has been removed. In this way, the rear sides 102 of the optoelectronic semiconductor chips 100 have been exposed. The film sections 510 of the reflecting film 500 previously resting on the rear sides 102 of the optoelectronic semiconductor chips 100 have also been removed. The exposure of the rear sides 102 of the optoelectronic semiconductor chips 100 can be carried out, for example, by a grinding process.

If the reflecting film 500 has an electrically conductive material, then the film sections 510 of the reflecting film 500 resting on the rear sides 102 of the optoelectronic semiconductor chips 100 do not necessarily have to be removed. In particular when the film sections 510 of the reflecting film 500 resting on the rear sides 102 of the optoelectronic semiconductor chips 100 have previously been connected integrally to the rear sides 102 of the optoelectronic semiconductor chips 100, the film sections 510 of the reflecting film 500 resting on the rear sides 102 of the optoelectronic semiconductor chips 100 can remain wholly or partly on the rear sides 102 of the optoelectronic semiconductor chips 100.

The exposure of the rear sides 102 of the optoelectronic semiconductor chips 100 or the film sections 510 of the reflecting film 500 resting on the rear sides 102 of the optoelectronic semiconductor chips 100 can alternatively also be carried out even before detachment of the molded body 600 from the carrier 400.

FIG. 6 shows a further sectioned side view of the molded body 600 in a processing state following the illustration of FIG. 5 chronologically.

Metallizations 700 have been arranged on the rear sides 102 of the optoelectronic semiconductor chips 100. The metallizations 700 produce electrically conductive contacts to rear-side contact pads 120 arranged on the rear sides 102 of the optoelectronic semiconductor chips 100. The metallizations 700 can be used to make electrical contact with the optoelectronic semiconductor chips 100 after processing has been completed.

If the film sections 510 of the reflecting film 500 resting on the rear sides 102 of the optoelectronic semiconductor chips 100 have remained on the rear sides 102 of the optoelectronic semiconductor chips 100, then the arrangement of the metallizations 700 can be omitted. In this case, the film sections 510 of the reflecting film 500 resting on the rear sides 102 of the optoelectronic semiconductor chips 100 can perform the task of the metallizations 700.

The metallizations 700 can also be arranged even before the detachment of the molded body 600 from the carrier 400.

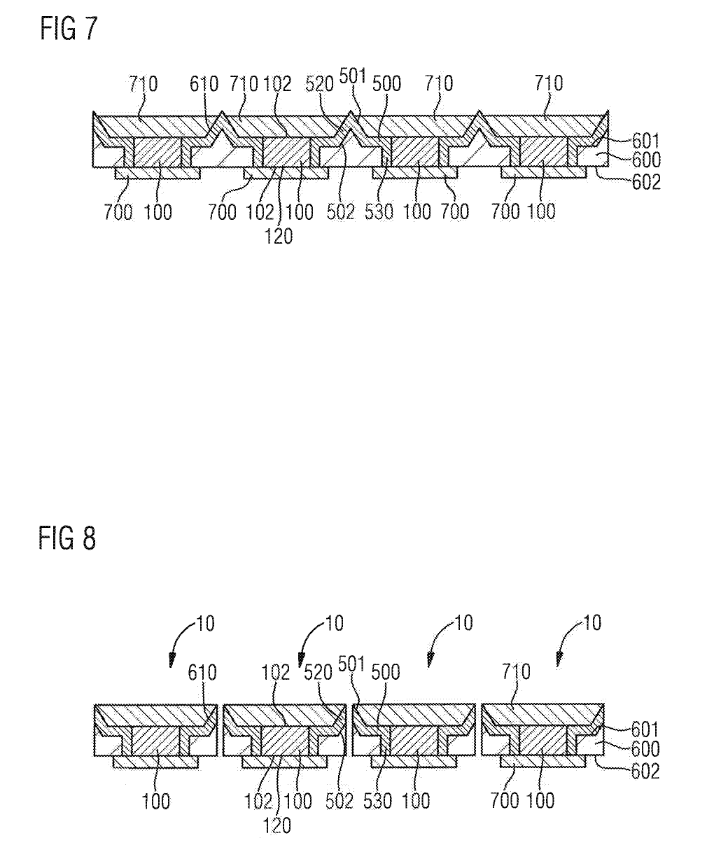

FIG. 7 shows a further schematic sectioned side view of the molded body 600 in a processing state following the illustration of FIG. 6 chronologically.

A wavelength-converting material 710 has been arranged over the front sides 101 of the optoelectronic semiconductor chips 100. The wavelength-converting material 710 can have been applied, for example, by a casting method, by injecting, by spraying or sputtering. The wavelength-converting material 710 can, for example, wholly or partly fill the reflectors 610 formed on the front side 601 of the molded body 600.

The wavelength-converting material 710 can, for example, have a matrix material, in particular silicone, for example, and wavelength-converting particles embedded in the matrix material. The wavelength-converting material 710 is provided to convert electromagnetic radiation emitted by the optoelectronic semiconductor chips 100 at least partly into electromagnetic radiation of another, for example, higher wavelength. The optoelectronic semiconductor chips 100 can, for example, be configured to emit electromagnetic radiation with a wavelength from the blue or ultraviolet spectral range. The wavelength-converting material 710 can, for example, be provided to convert electromagnetic radiation emitted by the optoelectronic semiconductor chips 100 into electromagnetic radiation with a wavelength from the yellow spectral range.

The arrangement of the wavelength-converting material 710 over the front sides 101 of the optoelectronic semiconductor chips 100 can also be omitted. Instead of the wavelength-converting material 710, another potting material can optionally be arranged over the front sides 101 of the optoelectronic semiconductor chips 100.

FIG. 8 shows a schematic sectioned side view of the molded body 600 in a processing state following the illustration of FIG. 7 chronologically.

The molded body 600 has been divided up to obtain a plurality of optoelectronic components 10. Each optoelectronic component 10 has a section of the molded body 600 with a reflector 610 and an optoelectronic semiconductor chip 100 embedded in the section of the molded body 600. The sections of the molded body 600 of the individual optoelectronic components 10 will likewise be designated as molded bodies 600 below, for simplicity.

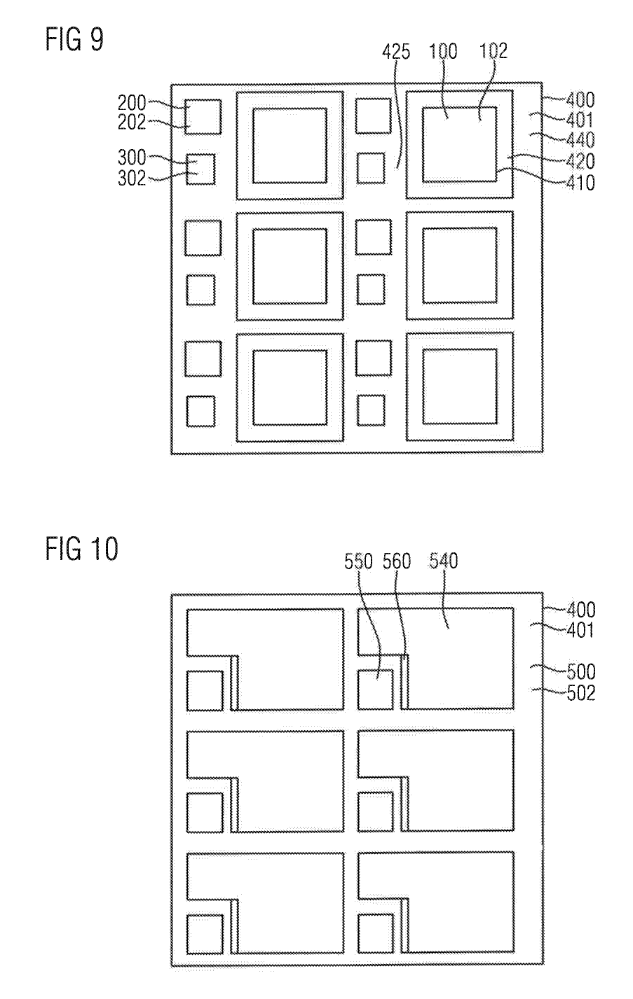

If the optoelectronic semiconductor chips 100 of the optoelectronic components 10 have front-side electric contact pads on their front sides 100, then electrically conductive through contacts can be embedded in the molded bodies 600 of the optoelectronic components 10 to produce electrically conductive connections between the front-side contact pads of the optoelectronic semiconductor chips 100 and the rear sides 602 of the molded bodies 600. In the following text, by using the FIGS. 9 to 12, 13 to 17 and 18 to 24, various exemplary possibilities of forming such through contacts will be described. The possibilities described below constitute variants of the production method described by using FIGS. 1 to 8 and, apart from the differences explained below, correspond to the method described by using FIGS. 1 to 8. The various possibilities described below can also be combined with one another.

FIG. 9 shows a schematic plan view of part of the upper side 401 of the carrier 400 with the film 440 arranged thereon. The island-like elevated regions 410 of the upper side 401 of the carrier 400 are delimited by the trench-like recessed regions 420. Between the individual recessed regions 420, the upper side 401 of the carrier 400 in the example shown in FIG. 9 has outer regions 425, of which the height in the direction perpendicular to the upper side 401 corresponds to the height of the elevated regions 410.

In each case, one of the optoelectronic semiconductor chips 100 is arranged over each elevated region 410 of the upper side 401 of the carrier 400. In addition, protective chips 200 and via chips 300 are arranged over the outer regions 425. Each optoelectronic semiconductor chip 100 is assigned a protective chip 200 and a via chip 300.

The protective chips 200 can be used to protect the optoelectronic semiconductor chips 100 against damage by electrostatic discharges. The protective chips 200 can have protective diodes, for example. Each protective chip 200 has a front side 201 and a rear side 202 opposite the front side 201. The protective chips 200 are arranged on the film 440 over the outer regions 425 of the upper side 401 of the carrier 400 such that the front sides 201 of the protective chips 200 face the upper side 401 of the carrier 400. The protective chips 200 can also be omitted.

The via chips 300 each have a front side 301 and a rear side 302 opposite the front side 301. Each via chip 300 is arranged on the film 440 over an outer region 425 of the upper side 401 of the carrier 400 such that the front side 301 faces the upper side 401 of the carrier 400.

The via chips 300 can have an electrically conductive or an electrically insulating material. If the via chips 300 have an electrically conductive material, they can, for example, have a metal or a doped semiconductor material. If the via chips 300 are non-conductive, then the via chips 300 can, for example, have a glass, plastic or a ceramic. In this case, the via chips 300 can, for example, also be formed as non-conductive spheres.

Between their front sides 201, 301 and their rear sides 202, 302, the protective chips 200 and the via chips 300 have a thickness which corresponds as exactly as possible to the thickness of the optoelectronic semiconductor chips 100 between the front sides 101 and the rear sides 102 of the latter.

FIG. 10 shows a schematic plan view of the upper side 401 of the carrier 400 in a processing state following the illustration of FIG. 9 chronologically.

The reflecting film 500 has been arranged over the rear sides 102, 202, 302 of the optoelectronic semiconductor chips 100, the protective chips 200 and the via chips 300.

In the example shown in FIG. 10, the reflecting film 500 has an electrically insulating material, for example, a plastic and on its front side 501 facing the chips 100, 200, 300 and the upper side 401 of the carrier 400, is coated in some sections with an electrically conductive material, for example, a metal. The reflecting film 500 has electrically conductive first film sections 540 and electrically conductive second film sections 550 insulated with respect to the first film sections 540. Each set of an optoelectronic semiconductor chip 100, a protective chip 200 and a via chip 300 is assigned a first film section 540 and a second film section 550. The first film section 540 is in contact with the rear side 102 of the optoelectronic semiconductor chip 100 and the rear side 202 of the protective chip 200. The second film section 550 is in contact with the rear side 302 of the via chip 300.

In addition, the reflecting film 500 in the example shown in FIG. 10 has openings 560 extending through the reflecting film 500 between the front side 501 and the rear side 502. Each pair of a first film section 540 and a second film section 550 is arranged an opening 560. In the example shown in FIG. 10, the opening 560 is respectively arranged between the first film section 540 and the second film section 550. However, the openings 560 could also be arranged at other positions. The openings 560 can also be omitted.

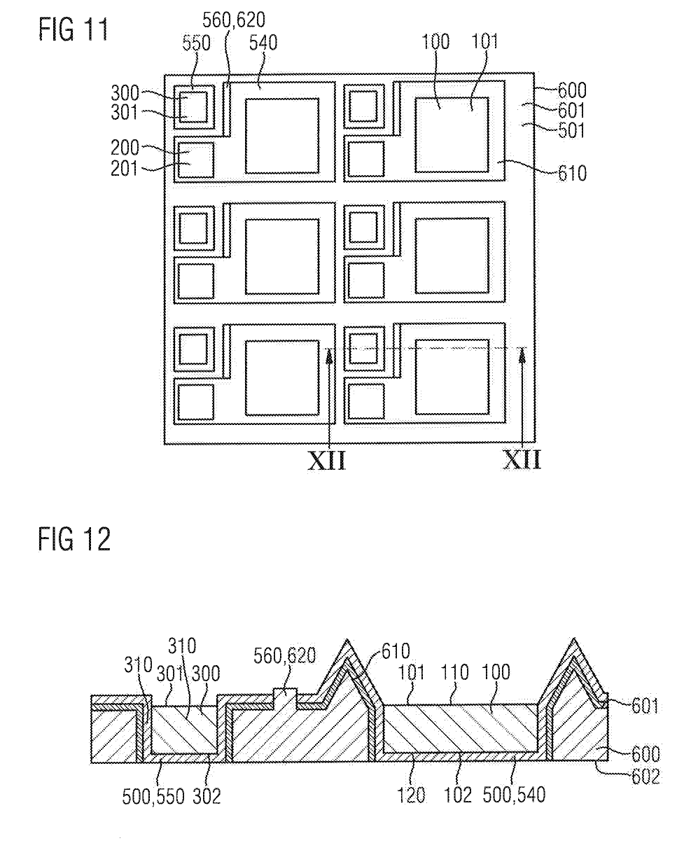

FIG. 11 shows a schematic plan view of the front side 501 of the reflecting film 500 in a processing state following the illustration of FIG. 10 chronologically, after the forming of the molded body 600 and the detachment of the film 440 arranged on the upper side 401 of the carrier 400. FIG. 12 shows a schematic sectioned side view of part of the molded body 600. The section runs through one of the optoelectronic semiconductor chips 100 and the via chip 300 assigned to the optoelectronic semiconductor chip 100.

The reflecting film 500 covers the front side 601 of the molded body 600 apart from those regions in which the front sides 101 of the optoelectronic semiconductor chips 100, the front sides 201 of the protective chips 200 and the front sides 301 of the via chips 300 are exposed. In particular, the reflecting film 500 covers the reflectors 610, formed in the recessed regions 420 of the upper side 401 of the carrier 400, on the front side 601 of the molded body 600.

In the regions of the openings 560 in the reflecting film 500, during the forming of the molded body 600, part of the material of the molded body 600 passes through the openings 560 in the reflecting film 500, by which anchorages 620 have been formed, at which the reflecting film 500 is anchored in the material of the molded body 600. This achieves a situation where the reflecting film 500 is fixed particularly reliably to the front side 601 of the molded body 600.

In the processing state shown in FIG. 12, the film sections 540, 550 arranged on the rear sides 102, 302 of the optoelectronic semiconductor chip 100 and the via chip 300 have already been exposed. Once more, removal of the film sections 540, 550 arranged on the rear sides 102, 302 of the optoelectronic semiconductor chip 100 and of the via chip 330, and therefore exposure of the rear side 102 of the optoelectronic semiconductor chip 100 and of the rear side 302 of the via chip 300, would likewise be possible.

In a following processing step, once more the metallization 700 can be arranged on the rear side 102 of the optoelectronic semiconductor chip 100 or on the first film section 540 arranged on the rear side 102 of the optoelectronic semiconductor chip 100 to make electric contact with the rear-side contact pad 120 of the optoelectronic semiconductor chip 100 that is located on the rear side 102 of the optoelectronic semiconductor chip 100.

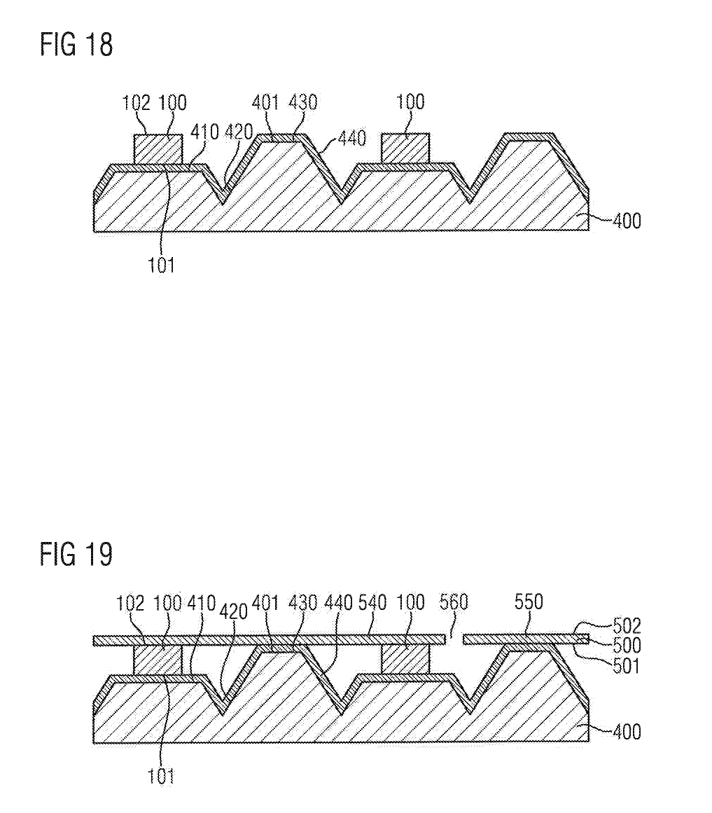

If the via chip 300 has an electrically conductive material, then the via chip 300 forms an electrically conductive through contact 310 extending through the molded body 600 from the front side 601 to the rear side 602 of the molded body 600. In this case, in a following processing step a further metallization can be arranged on the rear side 302 of the via chip 300 or on the second film section 550 covering the rear side 302 of the via chip 300 to make electric contact with the via chip 300 on the rear side 602 of the molded body 600. In addition, in this case, in a further following processing step, which will be explained below by way of example using FIGS. 18 to 24, on the front side 601 of the molded body 600 an electrically conductive connection can be produced between a front-side contact pad 110 arranged on the front side 101 of the optoelectronic semiconductor chip 100 and the front side 301 of the via chip 300. As a result, it is made possible to make contact both with the rear-side contact pad 120 and with the front-side contact pad 110 of the optoelectronic semiconductor chip 100 on the rear side 602 of the molded body 600.

If the via chip 300 has a non-conductive material, then a part of the second film section 550 enclosed between the via chip and the material of the molded body 600 forms the electrically conductive through contact 310 extending through the molded body 600 between the front side 601 and the rear side 602. In this case, the part of the second film section 550 that covers the rear side 302 of the via chip 300 expediently remains on the rear side 302 of the via chip 300. In addition, in this case, a metallization can also be provided in the region of the rear side 302 of the via chip 300. Furthermore, in this case on the front side 601 of the molded body 600, an electrically conductive connection is created between the front-side contact pad 110 of the optoelectronic semiconductor chip 100 and the second film section 550 to create an electrically conductive connection between the metallization arranged in the region of the rear side 302 of the via chip 300 and the front-side contact pad 110 of the optoelectronic semiconductor chip 100.

The rear side 202 of the protective chip 200 electrically conductively connects via the electrically conductive first film section 540 of the reflecting film 500 to the rear-side contact pad 120 of the optoelectronic semiconductor chip 100 that is arranged on the rear side 102 of the optoelectronic semiconductor chip 100. The front side 201 of the protective chip 200 connects via a further electrically conductive connection on the front side 601 of the molded body 600 to the front-side contact pad 110 of the optoelectronic semiconductor chip 100 that is arranged on the front side 101 of the optoelectronic semiconductor chip 100 and/or to the through contact 310. The protective chip 200 then connects electrically in parallel with the optoelectronic semiconductor chip 100 and can protect the optoelectronic semiconductor chip 100 against damage by electrostatic discharges.

The further processing in the method illustrated by using FIGS. 9 to 12 is carried out as in the method explained by using FIGS. 1 to 8.

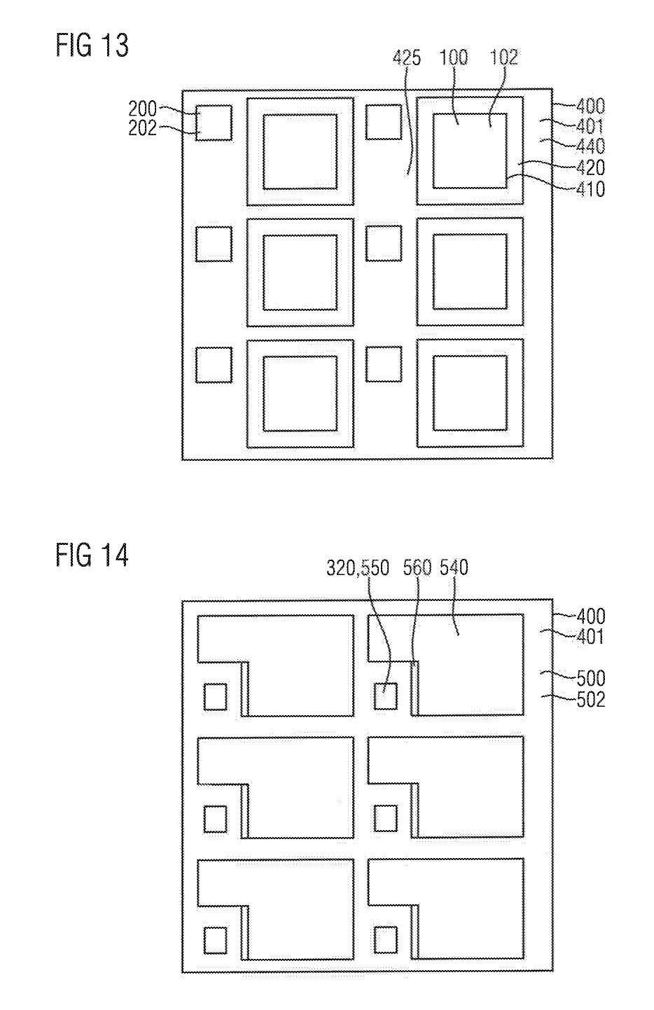

FIG. 13 shows a plan view of part of the upper side 401 of the carrier 400 with the film 440 arranged thereon. As in the illustration of FIG. 9, the upper side 401 has elevated regions 410, recessed regions 420 delimiting the elevated regions 410 and outer regions 425 surrounding the recessed regions 420. The optoelectronic semiconductor chips 100 are arranged over the elevated regions 410 of the upper side 401 of the carrier 400. The protective chips 200 are arranged over the outer regions 425. There are no via chips 300 in the illustration of FIG. 13.

FIG. 14 shows a schematic plan view of the rear side 502 of the reflecting film 500 after the reflecting film 500 has been arranged over the optoelectronic semiconductor chips 100 and the protective chips 200 in a processing step following the illustration of FIG. 13 chronologically.

The reflecting film 500 again has electrically conductive first film sections 540 and electrically conductive second film sections 550 that are insulated with respect to the first film sections 540. In addition, the reflecting film 500 once more has openings 560, which are each arranged between a first film section 540 and a second film section 550, but can also be omitted.

Each electrically conductive first film section 540 is in contact with the rear side 102 and the rear-side contact pad 120, that is arranged on the rear side 102, of an optoelectronic semiconductor chip 100, and with the rear side 202 of a protective chip 200.

The second film sections 550 in the example shown in FIG. 14 each extend through the reflecting film 500, and are therefore accessible both on the front side 501 and on the rear side 502 of the reflecting film 500. In addition, the second film sections 550 on the front side 501 of the reflecting film 500 each have a via structure 320 with a thickness elevated above the front side 501 of the reflecting film 500. The via structures 320 on the front side 501 of the reflecting film 500 can be formed, for example, as bumps or pillars.

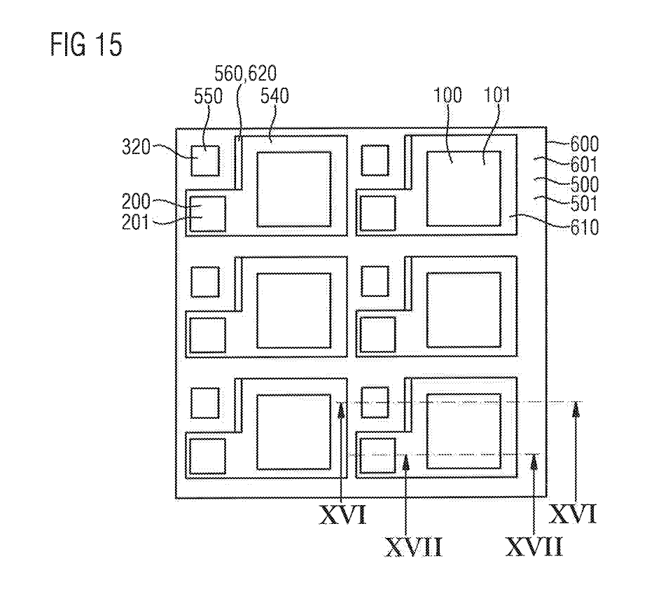

FIG. 15 shows a schematic plan view of the front side 601 of the molded body 600 with the reflecting film 500 arranged thereon, after the molded body 600 has been formed in the processing steps following the illustration of FIG. 14 chronologically and has been detached from the carrier 400.

As in the illustration of FIG. 11, the front sides 101 of the optoelectronic semiconductor chips 100 and the front sides 201 of the protective chips 200 are not covered by the material of the molded body 600 but are exposed on the front side 601 of the molded body 600. During forming of the molded body 600, part of the material of the molded body 600 has passed through the openings 560 in the reflecting film 500 and, as a result, has formed anchorages 620 which anchor the reflecting film 500 to the molded body 600.

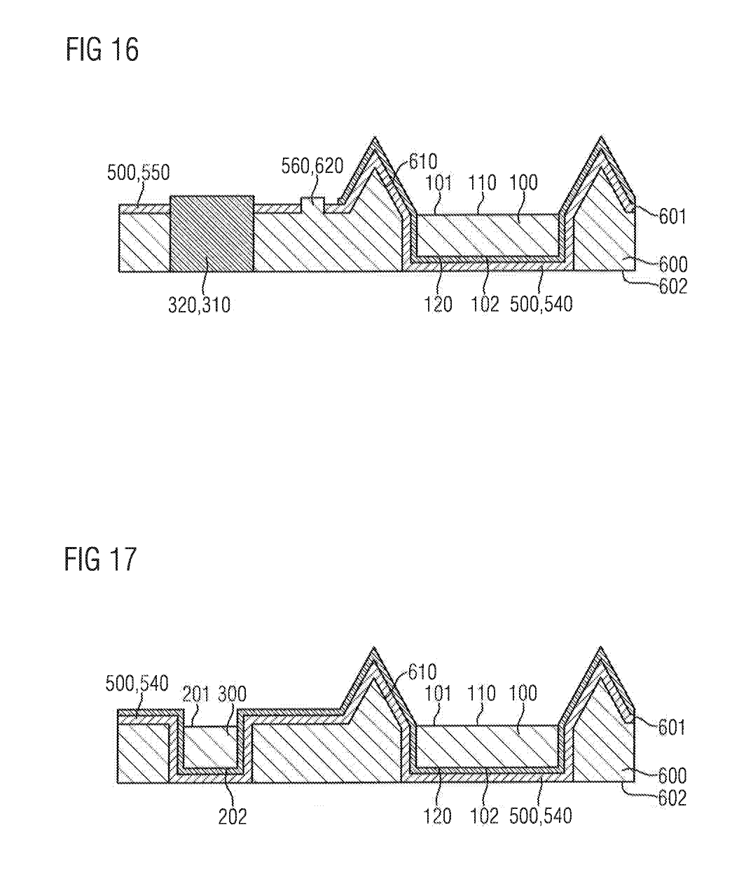

FIG. 16 shows a schematic sectioned side view of part of the molded body 600, the section extending through one of the optoelectronic semiconductor chips 100 and the second film section 550 assigned to the optoelectronic semiconductor chip 100. FIG. 17 shows a further sectioned side view of part of the molded body 600, the section extending through the optoelectronic semiconductor chip 100 and the protective chip 200 assigned to the optoelectronic semiconductor chip 100.

FIG. 16 shows that the via structure 320 of the second film section 550 extends through the molded body 600 from the front side 601 as far as the rear side 602 of the molded body 600 and, as a result, forms an electrically conductive through contact 310. In a following processing step, on the front side 601 of the molded body 600, an electrically conductive connection can be created between the front-side contact pad 110 of the optoelectronic semiconductor chip 100, that is arranged on the front side 101 of the optoelectronic semiconductor chip 100, and the through contact 310. Contact with the rear-side contact pad 120 of the optoelectronic semiconductor chip 100 can be made as in the example shown in FIG. 12.

FIG. 17 shows that the rear side contact pad 120 of the optoelectronic semiconductor chip 100 electrically conductively connects to the rear side 202 of the protective chip 200 via the first film section 540 of the reflecting film 500. As in the example of FIG. 12, in a following processing step a further electrically conductive connection can be created between the front-side contact pad 110 of the optoelectronic semiconductor chip 100 and the front side 201 of the protective chip 200 to connect the protective chip 200 electrically in parallel with the optoelectronic semiconductor chip 100.

FIG. 18 shows a schematic sectioned side view of the carrier 400 according to a further example of the method. As distinct from the illustration of FIG. 1, the upper side 401 of the carrier 400 in the illustration of FIG. 18 has further elevated regions 430 in addition to the elevated regions 410 and the recessed regions 420 enclosing the elevated regions 410 annularly. Each recessed region 420 is arranged between an elevated region 410 and a further elevated region 430. The further elevated regions 430 project beyond the elevated regions 410. The height difference between the further elevated regions 430 and the elevated regions 410 corresponds to the thickness of the optoelectronic semiconductor chips 100. As a result, the rear sides 102 of the optoelectronic semiconductor chips 100 arranged above the elevated regions 410 of the upper side 401 of the carrier 400 lie approximately in a common plane with the further elevated regions 430.

FIG. 19 shows a schematic sectioned side view of the carrier 400 in a processing state following the illustration of FIG. 18 chronologically.

The reflecting film 500 has been arranged over the rear sides 102 of the optoelectronic semiconductor chips 100 and over the further elevated regions 430 of the carrier 400. The front side 501 of the reflecting film 500 rests both on the rear sides 102 of the optoelectronic semiconductor chips 100 and also on the film 440 over the further elevated regions 430 of the upper side 401 of the carrier 400.

The reflecting film 500 is once more subdivided into electrically conductive first film sections 540 and electrically conductive second film sections 550 that are insulated electrically with respect to the first film sections 540. In each case, a first film section 540 rests on the rear side 102 of an optoelectronic semiconductor chip 100, while the associated second film section 550 is arranged over the further elevated region 430 of the upper side 401 of the carrier 400 which is assigned to the respective optoelectronic semiconductor chip 100.

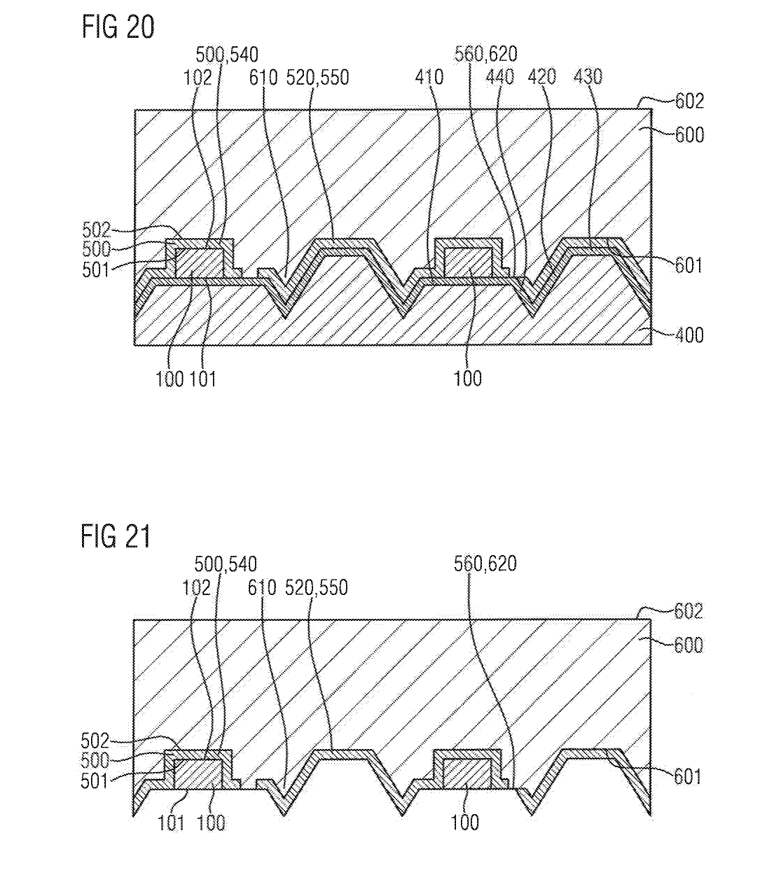

FIG. 20 shows a schematic sectioned side view of the carrier 400 in a processing state following the illustration of FIG. 19 chronologically.

The molded body 600 has been formed on the rear side 502 of the reflecting film 500 that faces away from the optoelectronic semiconductor chips 100. Once more, the molded body 600 has been formed such that its front side 601 at least partly reproduces the upper side 401 of the carrier 400.

FIG. 21 shows a schematic sectioned side view of the molded body 600 following the detachment of the molded body 600, the reflecting film 500 and the optoelectronic semiconductor chips 100 from the upper side 401 of the carrier 400.

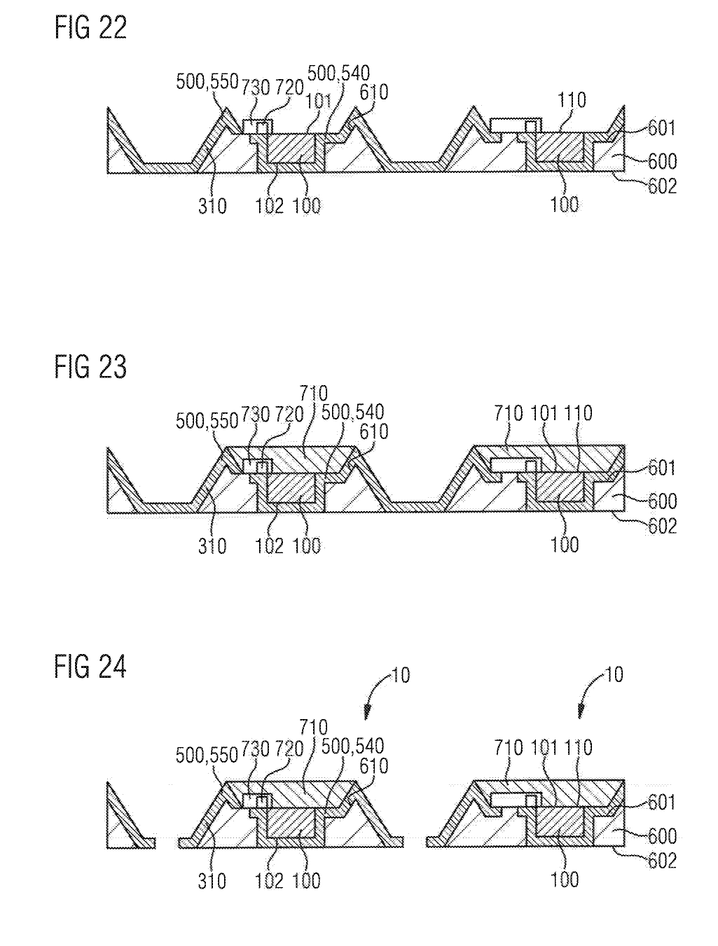

FIG. 22 shows a schematic sectioned side view of the molded body 600 in a processing state following the illustration of FIG. 21 chronologically.

On the rear side 602 of the molded body 600, part of the material of the molded body 600 has been removed so that, in each optoelectronic semiconductor chip 100, the first film section 540 of the reflecting film 500 that is arranged on the rear side 102 is now exposed.

In addition, on the rear side 602 of the molded body 600, the second film sections 550 arranged over the further elevated regions 430 of the upper side 401 of the carrier 400 during forming of the molded body 600 have been exposed. As a result, the second film sections 550 now form through contacts 310, which extend through the molded body 600 from the front side 601 of the molded body 600 as far as the rear side 602 of the molded body 600.

In further processing steps, on the front side 601 of the molded body 600, an electrically conductive connection 730 for each optoelectronic semiconductor chip 100 has been created, connecting the front-side contact pad 110 of the optoelectronic semiconductor chip 100 that is arranged on the front side 101 of the respective optoelectronic semiconductor chip 100 to the through contact 310 formed by the respectively associated second film section 550 of the reflecting film 500. To create the electrically conductive connections 730, in each case, first, a dielectric 720 has been arranged over the edge region of the front side 101 of the optoelectronic semiconductor chip 100 and part of the respective first film section 540. Then, the electrically conductive connection 730 was created, extending respectively from the front-side contact pad 110 on the front side 101 of the respective optoelectronic semiconductor chip 100, via the dielectric 720, to the associated second film section 550 on the front side 601 of the molded body 600. The dielectric 720 is used respectively to insulate the electrically conductive connection 730 electrically with respect to the first film section 540 that is connected to the rear-side contact pad 120 of the optoelectronic semiconductor chip 100.

FIG. 23 shows a schematic sectioned side view of the molded body 600 in a processing state following the illustration of FIG. 22 chronologically. The wavelength-converting material 710 has been arranged over the front sides 101 of the optoelectronic semiconductor chips 100.

FIG. 24 shows a schematic sectioned side view of the molded body 600 in a processing state following the illustration of FIG. 23 chronologically. A plurality of optoelectronic components 10 has been formed by dividing up the molded body 600.

In a further example of the method, the further elevated regions 430 of the carrier 400 project beyond the elevated regions 410 of the carrier 400, differing from the illustration of FIG. 18 such that the height difference between the further elevated regions 430 and the elevated regions 410 is greater than the thickness of the optoelectronic semiconductor chips 100. In this example, differing from the illustration of FIG. 22, part of the material of the molded body 600 is later removed on the rear side 602 of the molded body such that although the second film sections 550 arranged over the further elevated regions 430 of the upper side 401 of the carrier 400 during the forming of the molded body 600 are exposed, the first film sections 540 of the reflecting film 500 that are arranged on the rear sides 102 of the optoelectronic semiconductor chips 100 remain covered by the material of the molded body 600. Electric contact with the rear-side contact pads 120 of the optoelectronic semiconductor chip 100 is then made in the finished optoelectronic components 10 via the first film sections 540 connected electrically to the rear-side contact pads 120 of the optoelectronic semiconductor chips 100.

My components and methods have been illustrated and described in more detail by using preferred examples. Nevertheless, this disclosure is not restricted to the examples disclosed. Instead, other variations can be derived therefrom by those skilled in the art without departing from the protective scope of the appended claims.

This application claims priority of DE 10 2015 105 486.8, the subject matter of which is incorporated herein by reference.

1.-18. (canceled)

19. An optoelectronic component comprising an optoelectronic semiconductor chip at least partly enclosed by a molded body,
wherein a front side of the molded body is covered by a reflecting film, at least in some sections, and
a section of the reflecting film is enclosed between the optoelectronic semiconductor chip and the molded body.

20. The optoelectronic component according to claim 19, wherein the molded body forms on its front side a reflector elevated above a front side of the optoelectronic semiconductor chip, and
the reflector is covered by the reflecting film, at least in some sections.

21. The optoelectronic component according to claim 19, wherein a front side and a rear side of the optoelectronic semiconductor chip are not covered by the molded body.

22. The optoelectronic component according to claim 19, wherein the molded body has an electrically conductive through contact extending from the front side to a rear side of the molded body, and
there is an electrically conductive connection between an electric contact pad of the optoelectronic semiconductor chip, which is arranged on a front side of the optoelectronic semiconductor chip, and the electrically conductive through contact.

23. A method of producing an optoelectronic component comprising:
providing a carrier having an upper side which has an elevated and a recessed region;
arranging an optoelectronic semiconductor chip between the elevated region of the upper side of the carrier and a reflecting film, wherein a front side of the optoelectronic semiconductor chip faces the carrier, and a rear side of the optoelectronic semiconductor chip faces the reflecting film;
forming a molded body on a rear side of the reflecting film, facing away from the optoelectronic semiconductor chip, wherein the optoelectronic semiconductor chip is at least partly enclosed by the molded body, wherein a section of the reflecting film is enclosed between the optoelectronic semiconductor chip and the molded body; and
detaching the molded body, the reflecting film and the optoelectronic semiconductor chip from the upper side of the carrier, wherein at least part of the reflecting film remains on a front side of the molded body.

24. The method according to claim 23, wherein the molded body is formed such that the front side of the molded body at least partly reproduces the upper side of the carrier.

25. The method according to claim 23, wherein the molded body is formed such that the front side of the optoelectronic semiconductor chip is not covered by the material of the molded body.

26. The method according to claim 23, wherein the reflecting film integrally connects to the rear side of the optoelectronic semiconductor chip before forming the molded body.

27. The method according to claim 23, wherein the carrier has at least one opening, through which the reflecting film is sucked onto the upper side of the carrier before forming the molded body.

28. The method according to claim 23, wherein the reflecting film has at least one opening, and
during forming of the molded body, part of the material of the molded body passes through the opening in the reflecting film.

29. The method according to claim 23, further comprising:
arranging a wavelength-converting material over the front side of the optoelectronic semiconductor chip.

30. The method according to claim 23, wherein the reflecting film has an electrically conductive first film section and an electrically conductive second film section insulated with respect to the first film section.

31. The method according to claim 30, wherein an electrically conductive element is arranged on the rear side of the second film section of the reflecting film,
the molded body is formed such that, after forming the molded body, the electrically conductive element is accessible on a rear side of the molded body, and
following detachment from the carrier, the following step is carried out:
creating an electrically conductive connection between an electric contact pad of the optoelectronic semiconductor chip, that is arranged on the front side of the optoelectronic semiconductor chip, and the electrically conductive element.

32. The method according to claim 30, wherein an electrically conductive via chip is arranged between the upper side of the carrier and the second film section of the reflecting film and is enclosed by the molded body, and
following detachment from the carrier, the following step is carried out:
creating an electrically conductive connection between an electric contact pad of the optoelectronic semiconductor chip, that is arranged on the front side of the optoelectronic semiconductor chip, and the via chip.

33. The method according to claim 30, wherein a via chip is arranged between the upper side of the carrier and the second film section of the reflecting film and is enclosed by the molded body,
part of the second film section is enclosed between the via chip and the molded body, and
following detachment from the carrier, the following step is carried out:
creating an electrically conductive connection between an electric contact pad of the optoelectronic semiconductor chip, that is arranged on the front side of the optoelectronic semiconductor chip, and the second film section.

34. The method according to claim 30, wherein the carrier is provided with a further elevated region, and the recessed region is arranged between the elevated region and the further elevated region,
the first film section is arranged in contact with the rear side of the optoelectronic semiconductor chip, and the second film section is arranged to rest on the further elevated region, and
following detachment from the carrier, the following step is carried out:
creating an electrically conductive connection between an electric contact pad of the optoelectronic semiconductor chip, that is arranged on the front side of the optoelectronic semiconductor chip, and the second film section.

35. The method according to claim 23, further comprising:
exposing the rear side of the optoelectronic semiconductor chip; and
arranging a metallization on the rear side of the optoelectronic semiconductor chip.

36. The method according to claim 35, wherein the exposure of the rear side of the optoelectronic semiconductor chip comprises removal of part of the molded body on a rear side of the molded body.
